(19) United States
(12) Patent Application Publication
(10) Pub. No.: US 2024/0383012 A1
(43) Pub. Date: Nov. 21, 2024

(54) CLEANING APPARATUS, SEMICONDUCTOR FABRICATION SYSTEM INCLUDING THE SAME, AND SEMICONDUCTOR FABRICATION METHOD USING THE SAME

(71) Applicant: Samsung Electronics Co., Ltd., Suwon-si (KR)

(72) Inventors: Youngon OH, Suwon-si (KR); Jihun Kim, Suwon-si (KR); Sanghyuk Park, Suwon-si (KR)

(73) Assignee: SAMSUNG ELECTRONICS CO., LTD., Suwon-si (KR)

(21) Appl. No.: 18/384,633

(22) Filed: Oct. 27, 2023

(30) Foreign Application Priority Data
May 19, 2023 (KR) 10-2023-0065012

(51) Int. Cl. B08B 3/02; H01L 21/67

(52) U.S. Cl. CPC B08B 3/02; H01L 21/67023; H01L 21/67201; B08B 2203/0223

(57) ABSTRACT

Disclosed are cleaning apparatuses, semiconductor fabrication systems, and semiconductor fabrication methods. The cleaning apparatus comprises a housing that provides an inner space and a cleaning unit combined with the housing. The housing includes a slit that is upwardly recessed from a bottom surface of the housing and is connected to the inner space and a plurality of placement holes that upwardly extend from the bottom surface of the housing. The cleaning unit includes an intake device in the inner space and an intake pipe one end of which is connected to the intake device and another end of which is connected to the slit.

### CROSS-REFERENCE TO RELATED APPLICATION

This U.S. nonprovisional application claims priority under 35 U.S.C § 119 to Korean Patent Application No. 10-2023-0065012 filed on May 19, 2023 in the Korean Intellectual Property Office, the disclosure of which is hereby incorporated by reference in its entirety.

### BACKGROUND

### 1. Field

The present disclosure relates to a cleaning apparatus, a semiconductor fabrication system, and a semiconductor fabrication method, and more particularly, to a cleaning apparatus capable of removing particles occurring in overhead hoist transport (OHT) rails, a semiconductor fabrication system including the same, and a semiconductor fabrication method using the same.

### 2. Description of Related Art

A semiconductor device may be fabricated through various processes. For example, the semiconductor device may be manufactured through a photolithography process, an etching process, a deposition process, and a plating process that are performed on a substrate. To allow the substrate to undergo a process, it may be needed to load the substrate on a substrate processor. Before the substrate is inserted into the substrate processor, it may be required to place the substrate on a loadport. Various substrate transfer machines may be used to place the substrate on the loadport. For example, an OHT may be utilized to transfer the substrate. The OHT may transfer the substrate while moving along an OHT rail.

### SUMMARY

The present disclosure provides a cleaning apparatus capable of removing contaminants such as particles from a loadport, a semiconductor fabrication system including the same, and a semiconductor fabrication method using the same.

The present disclosure provides a cleaning apparatus capable of preventing diffusion of contaminants such as particles, a semiconductor fabrication system including the same, and a semiconductor fabrication method using the same.

The present disclosure provides a cleaning apparatus capable of cleaning a loadport by utilizing a conventional OHT rail, a semiconductor fabrication system including the same, and a semiconductor fabrication method using the same.

The object of the present disclosure is not limited to the foregoing, and other objects which have not been mentioned above will be clearly understood to those skilled in the art from the following description.

According to an aspect of the disclosure, a cleaning apparatus includes: a housing that provides an inner space; and a cleaner at least partially disposed within the inner space, wherein the housing comprises: a slit that is upwardly recessed from a bottom surface of the housing and is connected to the inner space; and a plurality of placement holes that upwardly extend from the bottom surface of the housing, and wherein the cleaner comprises: an intake device disposed within the inner space; and an intake pipe comprising a first end and a second end, wherein the first end is connected to the intake device and the second end is connected to the slit.

The cleaner may further include a nozzle cover disposed within the slit, wherein the nozzle cover includes a nozzle hole that vertically penetrates the nozzle cover, and wherein the second end of the intake pipe is connected to the nozzle hole.

The slit may extends horizontally in a first direction, an at least one of the plurality of placement holes may not overlap the slit.

A width of the slit in a second direction may decrease in an upward direction, the second direction being a horizontal direction that intersects the first direction.

The housing may further include a sensor receiving hole that is upwardly recessed from the bottom surface of the housing, and the sensor receiving hole may not overlap any of the slit and the plurality of placement holes.

A thickness of the sensor receiving hole may be in a range of about 5 mm to about 11 mm.

The plurality of placement holes may consist of three placement holes, and the three placement holes may be disposed to constitute a triangular shape when viewed in plan.

The intake device may include: a pump connected to the first end of the intake pipe; and an intake motor configured to drive the pump.

According to an aspect of the disclosure, a semiconductor fabrication system includes: an overhead hoist transport (OHT) rail: a first OHT configured to move along the OHT rail; and a cleaning apparatus attached to the first OHT, wherein the cleaning apparatus includes: a housing that provides an inner space; and a cleaner configured to remove a particle in a space below the housing, and wherein the cleaner is at least partially disposed within the inner space and is exposed to an exterior of the housing on a bottom surface of the housing.

The housing may include a slit that is upwardly recessed from the bottom surface of the housing and is connected to the inner space, and the cleaner may include: an intake device disposed within the inner space; and an intake pipe including a first end and a second end, wherein the first end is connected to the intake device and the second end is connected to the slit.

The cleaner may include: a brush that extends horizontally in a first direction; and a brush driver configured to cause the brush to move horizontally in a second direction that intersects the first direction, and wherein a lower end of the brush is located below the bottom surface of the housing.

The first OHT may include: an OHT body that provides an accommodation space; and a hoist attached to the OHT body and extending vertically, wherein the hoist is attached to the cleaning apparatus, and wherein the cleaning apparatus is connected to the OHT body through the hoist.

The semiconductor fabrication system may further include: a second OHT configured to move along the OHT rail; and a substrate delivery apparatus attached to the second OHT, wherein the substrate delivery apparatus includes one of a cassette and a front opening unified pod.

The semiconductor fabrication system may further include a loadport that is downwardly spaced apart from the OHT rail, wherein the loadport includes: a support plate; and a plurality of pins that upwardly extend from a top surface of the support plate.

The semiconductor fabrication system may further include: a substrate processor that is spaced apart in a horizontal direction from the loadport, wherein the substrate processor includes at least one of an etching chamber, a deposition chamber, a polishing chamber, an ion implantation chamber, a metal line process chamber, a measurement chamber, a photolithography chamber, and a cleaning chamber.

According to an aspect of the disclosure, a semiconductor fabrication method includes: placing a substrate through a loadport on a substrate processor: processing the substrate using the substrate processor: unloading the substrate through the loadport from the substrate processor: placing a cleaner on the loadport using a first overhead hoist transport (OHT) that is upwardly spaced apart from the loadport; and removing a particle on the loadport using the cleaner.

The placing the cleaner on the loadport using the first OHT may include: moving the first OHT along an OHT rail upwardly spaced apart from the loadport; and lowering the cleaner using a hoist of the first OHT.

The placing the substrate through the loadport on the substrate processor may include: placing the substrate on the loadport using a second OHT, wherein the second OHT is configured to move along the OHT rail; and transferring the substrate from the loadport to the substrate processor.

The cleaner may include: an intake device; and an intake pipe comprising a first end and a second end, wherein the first end is connected to the intake device and the second end is disposed on the loadport, and removing the particle on the loadport using the cleaner may include causing the intake device to cause the particle on the loadport to be drawn in through the intake pipe.

The cleaner may include: a brush that extends horizontally in a first direction; and a brush driver configured to cause the brush to move horizontally in a second direction that intersects the first direction, and removing the particle on the loadport using the cleaner may include causing the brush to move in the second direction.

Details of other example embodiments are included in the description and drawings.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a perspective view showing a semiconductor fabrication system according to one or more embodiments of the present disclosure:

FIGS. 2 and 3 illustrate perspective views showing a state where a cleaner is combined with an OHT according to one or more embodiments of the present disclosure:

FIG. 4 illustrates a perspective view showing a cleaner according to one or more embodiments of the present disclosure:

FIG. 5 illustrates an exploded perspective view showing a cleaner according to one or more embodiments of the present disclosure:

FIG. 6 illustrates a perspective view showing a housing of a cleaner according to one or more embodiments of the present disclosure:

FIG. 7 illustrates a bottom view showing a housing of a cleaner according to one or more embodiments of the present disclosure:

FIG. 8 illustrates an enlarged exploded perspective view partially showing a cleaner according to some embodiments of the present disclosure.

FIG. 9 illustrates an enlarged exploded perspective view partially showing a semiconductor fabrication system according to one or more embodiments of the present disclosure:

FIG. 10 illustrates a cross-sectional view showing a substrate processor according to one or more embodiments of the present disclosure:

FIG. 11 illustrates a cross-sectional view showing a substrate processor according to one or more embodiments of the present disclosure:

FIG. 12 illustrates a flow chart showing a semiconductor fabrication method according to one or more embodiments of the present disclosure:

FIGS. 13 to 15 illustrate diagrams showing a semiconductor fabrication method according to the flow chart of FIG. 12:

FIG. 16 illustrates a perspective view showing a cleaner according to one or more embodiments of the present disclosure; and

FIG. 17 illustrates an exploded perspective view showing a cleaner according to one or more embodiments of the present disclosure.

### DETAILED DESCRIPTION

The following will now describe one or more embodiments of the present disclosure with reference to the accompanying drawings. Like reference numerals may indicate like components throughout the description.

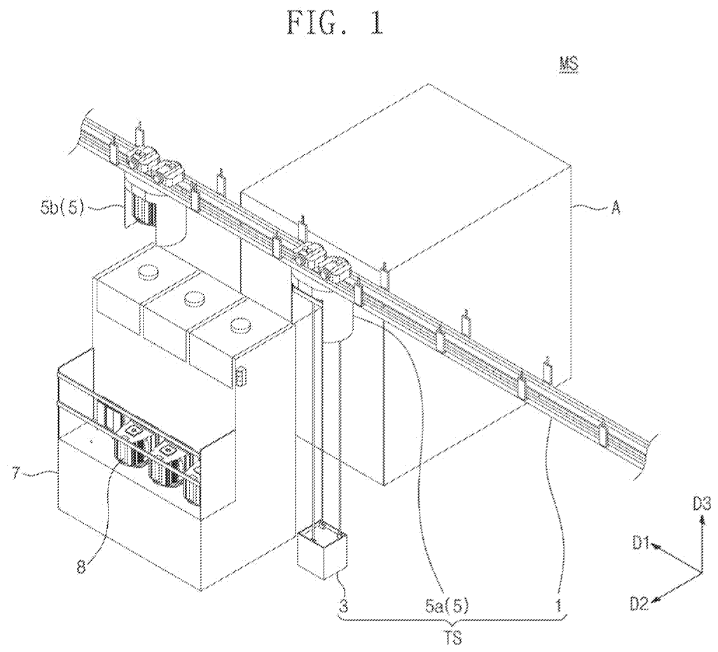

FIG. 1 illustrates a perspective view showing a semiconductor fabrication system according to one or more embodiments of the present disclosure.

In this description, symbol D1 may indicate a first direction, symbol D2 may indicate a second direction that intersects the first direction D1, and symbol D3 may indicate a third direction that intersects each of the first direction D1 and the second direction D2. Each of the first and second directions D1 and D2 may be called a horizontal direction. The third direction D3 may be called a vertical direction or an upward direction.

Referring to FIG. 1, a semiconductor fabrication system MS may be provided. The semiconductor fabrication system MS may be configured to process a substrate to manufacture a semiconductor device. A term “substrate” used in this description may denote a silicon (Si) wafer, but the present disclosure is not limited thereto. A variety of processes may be performed on a substrate to fabricate a semiconductor device. A substrate may be transferred to diverse locations. The semiconductor fabrication system MS may include a substrate processor A, a substrate loader 7, and a transfer system TS.

The substrate processor A may perform various processes on a substrate. For example, the substrate processor A may be configured to allow a substrate to undergo one or more of an etching process, a cleaning process, a deposition process, an ion implantation process, a metal line process, a measurement process, and a photolithography process. The substrate processor A may include at least one selected from an etching chamber, a deposition chamber, a polishing chamber, an ion implantation chamber, a metal line process chamber, a measurement chamber, a photolithography chamber, and a cleaning chamber. The substrate processor A will be further discussed in detail below.

The substrate loader 7 may load and unload a substrate into or from the substrate processor A. For example, a substrate may be inserted through the substrate loader 7 into the substrate processor A. In addition, a substrate released from the substrate processor A may be outwardly transferred through the substrate loader 7. For example, the substrate loader 7 may be a front end module (FEM). The substrate loader 7 will be further discussed in detail below.

The transfer system TS may transfer a substrate. For example, the transfer system TS may transfer a substrate to the substrate loader 7. In addition, the transfer system TS may clean the substrate loader 7. The transfer system TS may include an overhead hoist transport (OHT) rail 1, an OHT 5, a cleaning apparatus 3, and a substrate delivery apparatus 8.

The OHT rail 1 may extend in a horizontal direction. The OHT rail 1 may be upwardly spaced apart from the substrate loader 7.

The OHT 5 may move along the OHT rail 1. The OHT 5 may be provided in plural. For example, a first OHT Sa and a second OHT 5b may be provided. Unless otherwise specifically stated, a single OHT 5 will be discussed below.

The cleaning apparatus 3 may be combined with the OHT 5. The cleaning apparatus 3 may be combined with the first OHT Sa. The cleaning apparatus 3 may be transported by the OHT 5. For example, the first OHT Sa may place the cleaning apparatus 3 on the substrate loader 7. The cleaning apparatus 3 may remove particles positioned in a space below the first OHT 5a. For example, the cleaning apparatus 3 may remove particles on the substrate loader 7. A detailed description thereof will be further discussed below.

The substrate delivery apparatus 8 may be combined with the second OHT 5b. The second OHT 5b may transport the substrate delivery apparatus 8 into which a substrate is inserted. The substrate delivery apparatus 8 may include one or more of a cassette and a front opening unified pod (FOUP). The substrate delivery apparatus 8 may be disposed on the substrate loader 7. The substrate processor A may receive a substrate in the substrate delivery apparatus 8 disposed on the substrate loader 7. A detailed description thereof will be further discussed below.

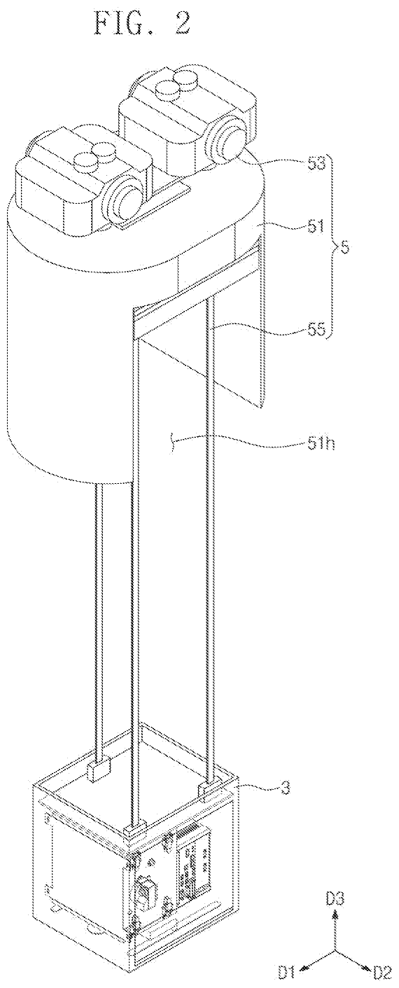

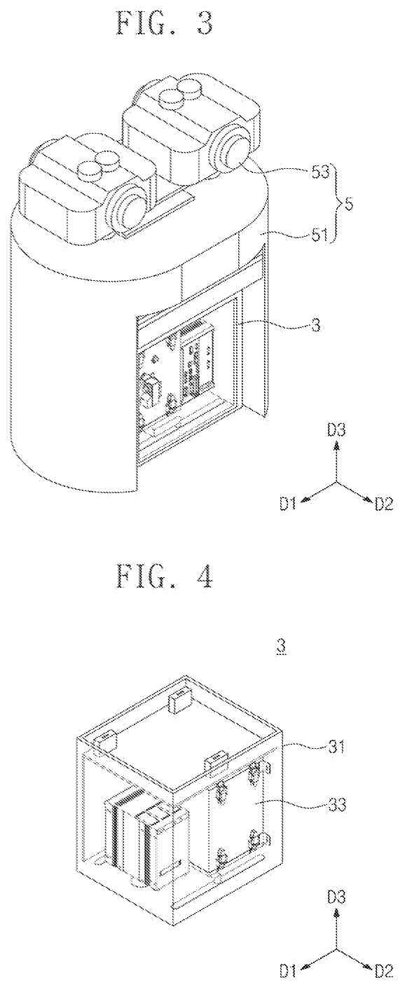

FIGS. 2 and 3 illustrate perspective views showing a state where a cleaner is combined with an OHT according to one or more embodiments of the present disclosure.

Referring to FIGS. 2 and 3, the OHT 5 may include an OHT body 51, a transfer wheel 53, and a hoist 55. The OHT body 51 may provide an accommodation space 51h. The accommodation space 51h may be exposed to a space below the OHT body 51. The cleaning apparatus 3 may be combined with the OHT body 51. For example, the cleaning apparatus 3 may be combined with the OHT body 51, while being inserted into the accommodation space 51h. The cleaning apparatus 3 may be exposed to a space below the OHT body 51.

The transfer wheel 53 may be combined with the OHT body 51. The transfer wheel 53 may move along the OHT rail (see 1 of FIG. 1). As the transfer wheel 53 moves along the OHT rail 1, the OHT body 51 may move. The hoist 55 may be combined with the OHT body 51. The hoist 55 may extend vertically.

The cleaning apparatus 3 may be combined through the hoist 55 with the OHT body 51. For example, the hoist 55 may be coupled to an upper end of the cleaning apparatus 3, and may combine the cleaning apparatus 3 with the OHT body 51. The cleaning apparatus 3 may vertically move through the hoist 55. For example, when a lower end of the hoist 55 moves downwardly, the cleaning apparatus 3 may move downwardly while departing from the OHT body 51.

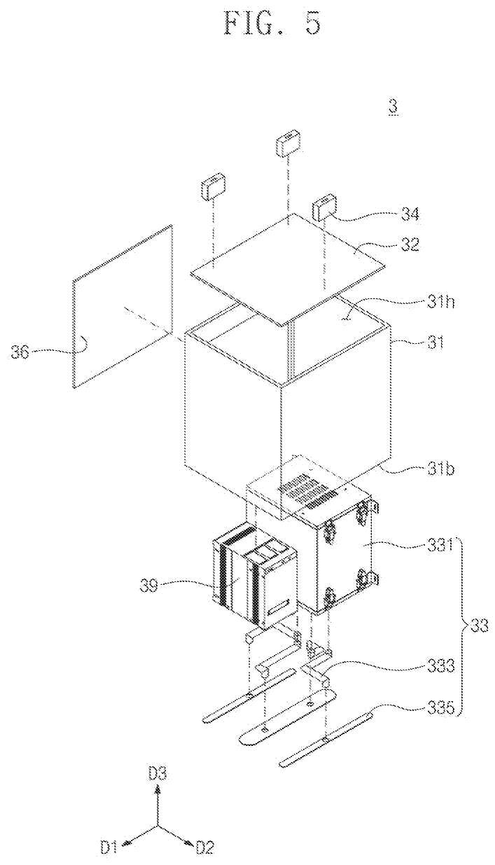

FIG. 4 illustrates a perspective view showing a cleaner according to one or more embodiments of the present disclosure. FIG. 5 illustrates an exploded perspective view showing a cleaner according to one or more embodiments of the present disclosure.

Referring to FIGS. 4 and 5, the cleaning apparatus 3 may include a housing 31, a cleaner 33, an upper cover 32, a side cover 36, a coupling member 34, and a controller 39.

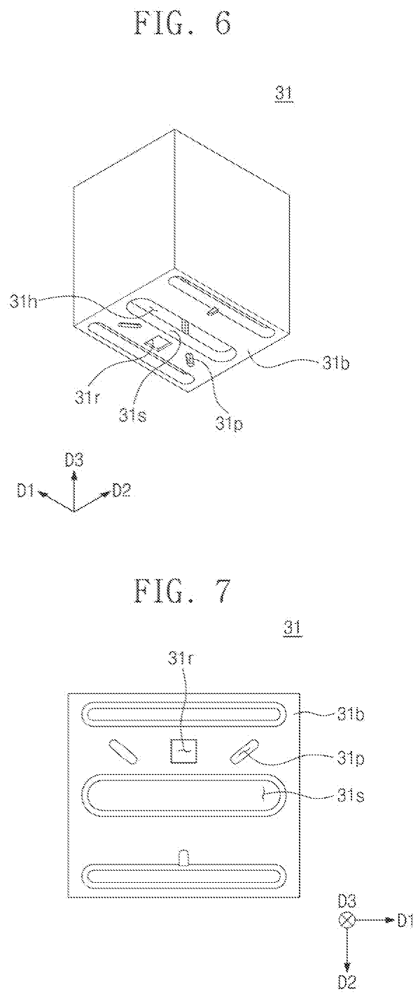

The housing 31 may provide an inner space 31h. The housing 31 may have a rectangular hexahedron shape, but the present disclosure is not limited thereto. The inner space 31h may be exposed to a space below the housing 31. A detailed description thereof will be further discussed below with reference to FIGS. 6 to 7.

The cleaner 33 may be combined with the housing 31. For example, the cleaner 33 may be combined with the housing 31 to allow the inner space 31h to accommodate at least a portion of the cleaner 33. The cleaner 33 may remove particles positioned in a space below the housing 31. The cleaner 33 may be exposed by a bottom surface 31b of the housing 31.

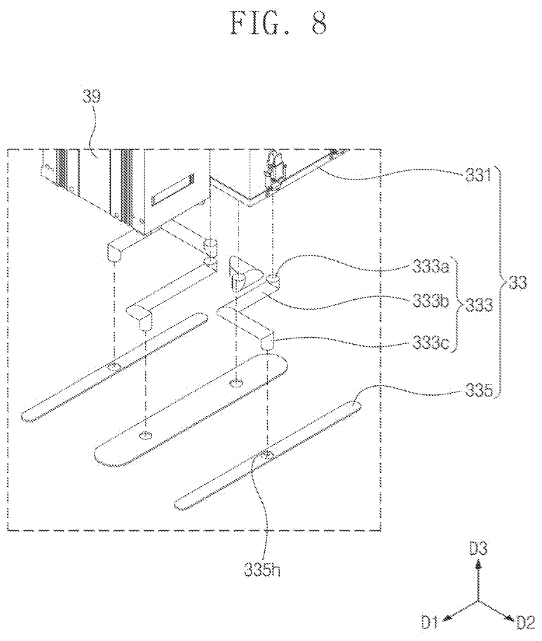

The cleaner 33 may use various methods to remove particles. For example, the cleaner 33 may use an intake method to remove particles. In this case, the cleaner 33 may include an intake device 331, an intake pipe 333, and a nozzle cover 335. The intake device 331 may absorb particles and the like. The intake device 331 may include a pump and an intake motor. The pump may be connected to an end of the intake pipe 333. The intake motor may drive the pump. The cleaner 33 will be further discussed in detail below with respect to FIG. 8.

The upper cover 32 may be coupled onto the housing 31. The upper cover 32 may cover the inner space 31h. The side cover 36 may be coupled onto one lateral surface of the housing 31. The coupling member 34 may be coupled onto the upper cover 32. The coupling member 34 may be combined with the hoist (see 55 of FIG. 2). For example, the housing 31 may be combined through the coupling member 34 with the hoist 55. The coupling member 34 may be provided in plural. For example, as shown in FIG. 5, three coupling members 34 may be provided. The three coupling members 34 may be disposed to constitute a triangular shape when viewed in plan.

The controller 39 may control the cleaner 33. For example, the controller 39 may control the intake device 331. In detail, the controller 39 may control the pump and the intake motor. The controller 39 may include one or more of a central processing unit (CPU) and a graphic processing unit (GPU).

The cleaning apparatus 3 may further include a battery. The battery may provide power to one or more of the cleaner 33 and the controller 39.

FIG. 6 illustrates a perspective view showing a housing of a cleaner according to one or more embodiments of the present disclosure. FIG. 7 illustrates a bottom view showing a housing of a cleaner according to one or more embodiments of the present disclosure.

Referring to FIGS. 6 and 7, the housing 31 may further provide a slit 31s, a placement hole 31p, and a sensor receiving hole 31r.

The slit 31s may be upwardly recessed from the bottom surface 31b of the housing 31. The slit 31s may be connected to the inner space 31h. The inner space 31h may be exposed through the slit 31s to a space below the housing 31. The slit 31s may extend in a horizontal direction. For example, the slit 31s may extend in the first direction D1. A length in the first direction D1 of the slit 31s may be less than a length in the first direction D1 of the housing 31. The slit 31s may be provided in plural. For example, three slits 31s may be provided. The plurality of slits 31s may be disposed spaced apart from each other in the second direction D2. The following will focus on a single slit 31s.

The placement hole 31p may upwardly extend from the bottom surface 31b of the housing 31. The placement hole 31p may not be connected to the inner space 31h. Therefore, a thickness of the placement hole 31p may be less than that of the slit 31s. In this description, the thickness of the placement hole 31p and the thickness of the slit 31s may respectively indicate a length in the third direction D3 of the placement hole 31p and a length in the third direction D3 of the slit 31s. The present disclosure, however, is not limited thereto, and the placement hole 31p may be connected to the inner space 31h. A length in the first direction D1 of the placement hole 31p may be less than a length in the first direction D1 of the slit 31s.

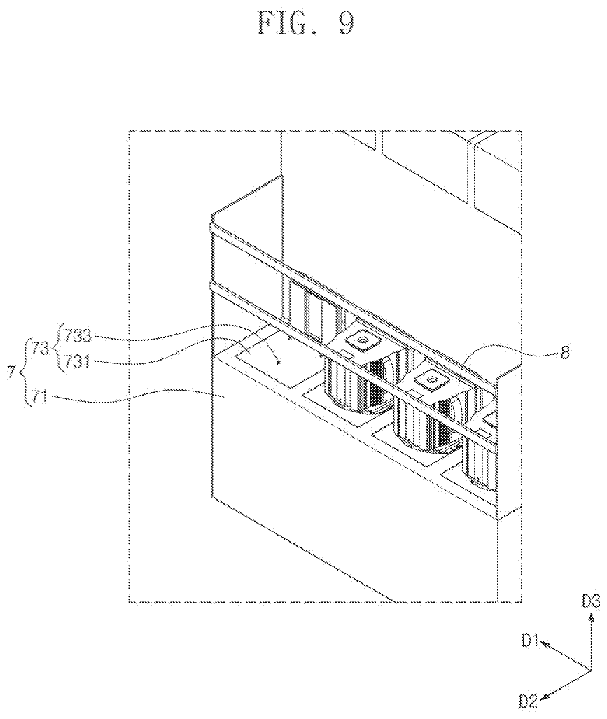

In a state where the cleaning apparatus (see 3 of FIG. 5) is placed on the substrate loader (see 7 of FIG. 1), a support pin (see 733 of FIG. 9) may be inserted into the placement hole 31p. For example, as the support pin 733 is inserted into the placement hole 31p, the cleaning apparatus 3 may be fixed to the substrate loader 7. A detailed description thereof will be further discussed below.

The placement hole 31p may be provided in plural. For example, as shown in FIG. 7, three placement holes 31p may be provided. The three placement holes 31p may be disposed to constitute a triangular shape when viewed in plan. At least one of the plurality of placement holes 31p may not overlap the slit 31s. A single placement hole 31p will be discussed in the interest of convenience.

The sensor receiving hole 31r may be upwardly recessed from the bottom surface 31b of the housing 31. The sensor receiving hole 31r may have a rectangular shape when viewed in plan, but the present disclosure is not limited thereto. The sensor receiving hole 31r may not overlap the slit 31s and/or the placement hole 31p. For example, when viewed in plan, the sensor receiving hole 31r may not overlap the slit 31s and/or the placement hole 31p. The sensor receiving hole 31r may have a thickness of about 5 mm to about 11 mm. For example, the sensor receiving hole 31r may have a thickness of about 8 mm. The thickness of the sensor receiving hole 31r may indicate a length in the third direction D3 of the sensor receiving hole 31r. A sensor may be inserted into the sensor receiving hole 31r. When the sensor receiving hole 31r has a thickness of about 5 mm to about 11 mm, a sensor of the substrate loader 7 may be inserted into the sensor receiving hole 31r without being pressed. A detailed description thereof will be further discussed below.

FIG. 8 illustrates an enlarged exploded perspective view partially showing a cleaner according to one or more embodiments of the present disclosure.

Referring to FIG. 8, the nozzle cover 335 may provide a nozzle hole 335h. The nozzle hole 335h may vertically penetrate the nozzle cover 335. Therefore, the nozzle hole 335h may connect a top surface of the nozzle cover 335 to a bottom surface of the nozzle cover 335. The nozzle cover 335 may be inserted into the slit (see 31s of FIG. 6). In a state where the nozzle cover 335 is inserted into the slit 31s, the inner space (see 31h of FIG. 5) may be exposed through the nozzle hole 335h to a space below the housing (see 31 of FIG. 5).

One end 333a of the intake pipe 333 may be connected to the intake device 331. Another end 333c of the intake pipe 333 may be connected to the slit 31s. For example, the another end 333c of the intake pipe 333 may be disposed in the slit 31s, while being inserted into the nozzle hole 335h. An intake pipe body 333b may connect the one end 333a of the intake pipe 333 to the another end 333c of the intake pipe 333. The intake device 331 may be connected through the intake pipe 333 to a space below the housing 31.

FIG. 9 illustrates an enlarged exploded perspective view partially showing a semiconductor fabrication system according to one or more embodiments of the present disclosure.

Referring to FIG. 9, the substrate loader 7 may include a loading body 71 and a loadport 73. The loading body 71 may support the loadport 73. The loadport 73 may be positioned on the loading body 71. The loadport 73 may be downwardly spaced apart from the OHT rail (see 1 of FIG. 1). For example, the OHT rail 1 may pass through a space on the loadport 73. The loadport 73 may be provided thereon with one or more of the cleaning apparatus (see 3 of FIG. 1) and the substrate delivery apparatus (see 8 of FIG. 1). The loadport 73 may include a support plate 731 and a support pin 733. The support plate 731 may have a rectangular shape when viewed in plan, but the present disclosure is not limited thereto.

The support pin 733 may upwardly extend from a top surface of the support plate 731. The support pin 733 may be provided in plural. For example, as shown in FIG. 9, three support pins 733 may be provided on one support plate 731. The three support pins 733 may be disposed to constitute a triangular shape when viewed in plan. A single support pin 733 will be discussed below. The loadport 73 may be provided in plural. For example, as shown in FIG. 9, four loadports 73 may be provided on one loading body 71. The plurality of loadports 73 may be disposed spaced apart from each other in a horizontal direction. A single loadport 73 will be discussed below.

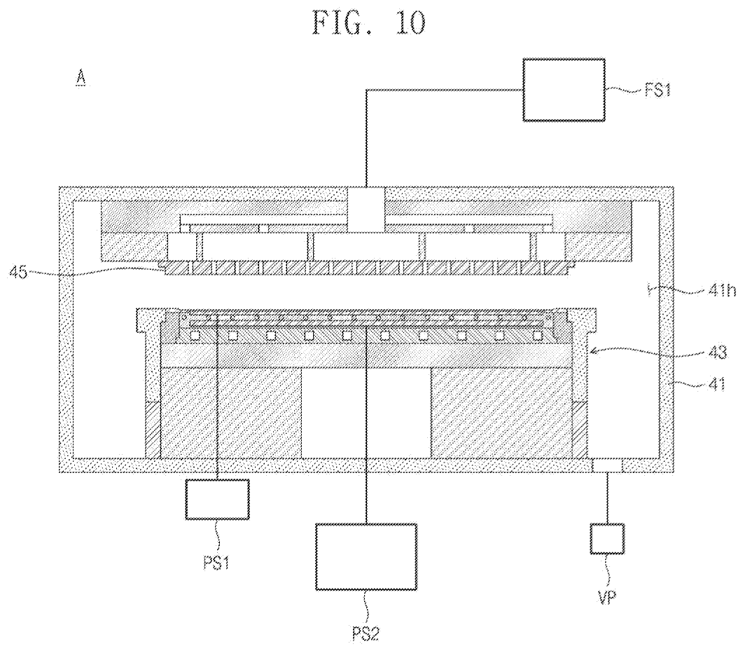

FIG. 10 illustrates a cross-sectional view showing a substrate processor according to one or more embodiments of the present disclosure.

Referring to FIG. 10, the substrate processor A may include an etching chamber. In this case, the substrate processor A may include an etching housing 41, an etching chuck 43, a showerhead 45, a first fluid supply FS1, a first power supply PS1, a second power supply PS2, and a vacuum pump VP.

The etching housing 41 may provide an etching space 41h. The etching chuck 43 may be positioned in the etching space 41h. The etching chuck 43 may support and/or fix a substrate. The showerhead 45 may be disposed upwardly spaced apart from the etching chuck 43. The first fluid supply FS1 may supply the etching space 41h with a fluid. The first fluid supply FS1 may be connected through the showerhead 45 to the etching space 41h. The first power supply PS1 may supply the etching chuck 43 with a first power. The first power may be, for example, a radio-frequency (RF) power. The second power supply PS2 may supply the etching chuck 43 with a second power. The second power may be, for example, a direct-current (DC) power. The vacuum pump VP may provide the etching space 41h with a vacuum pressure.

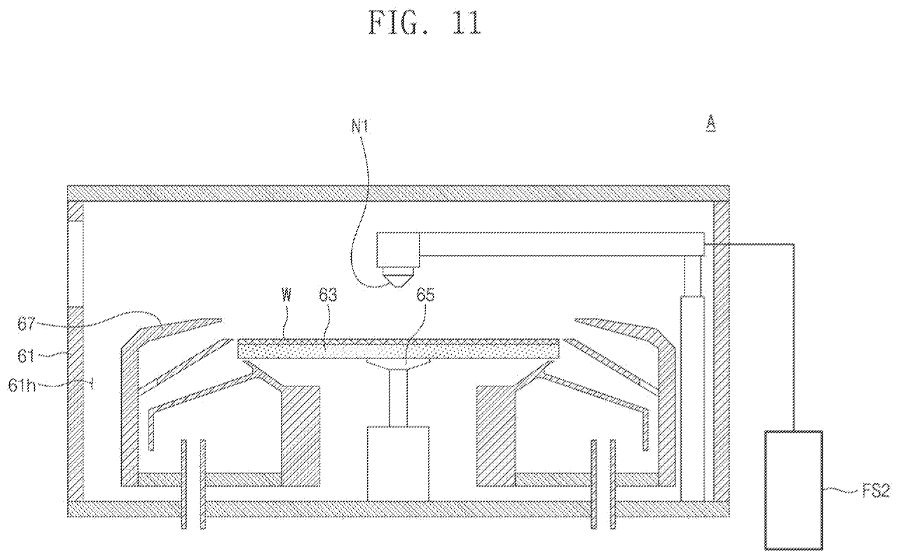

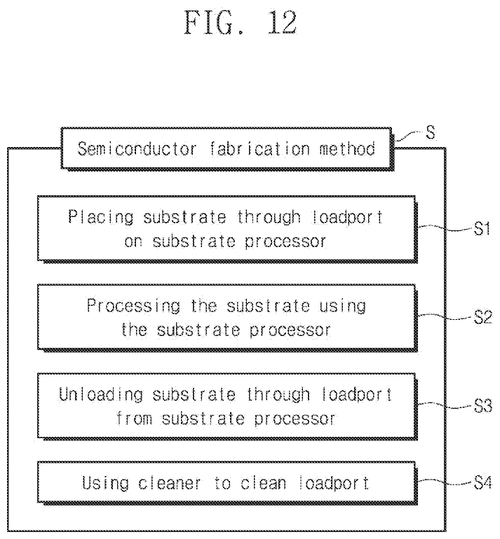

FIG. 11 illustrates a cross-sectional view showing a substrate processor according to one or more embodiments of the present disclosure.

Referring to FIG. 11, the substrate processor A may include a cleaning chamber. In this case, the substrate processor A may include a cleaning chamber 61, a cleaning stage 63, a rotational driving mechanism 65, a cleaning nozzle N1, a cleaning bowl 67, and a second fluid supply FS2.

The cleaning chamber 61 may provide a cleaning space 61h. In the cleaning chamber 61, a cleaning process may be performed on a substrate W.

The cleaning stage 63 may be positioned in the cleaning chamber 61. The cleaning stage 63 may support the substrate W.

The rotational driving mechanism 65 may drive the cleaning stage 63 to rotate. Therefore, the substrate W on the cleaning stage 63 may rotate.

The cleaning nozzle N1 may be disposed upwardly spaced apart from the cleaning stage 63. The cleaning nozzle N1 may be connected to the second fluid supply FS2. A fluid may be provided from the second fluid supply FS2 to the cleaning nozzle N1, thereby being sprayed onto the substrate W. The fluid sprayed from the cleaning nozzle N1 may clean the substrate W on the cleaning stage 63. In this operation, the cleaning stage 63 may allow the substrate W to rotate. The fluid in contact with a top surface of the substrate W that rotates may be pushed outwardly.

The cleaning bowl 67 may surround the cleaning stage 63. The cleaning bowl 67 may collect the fluid pushed from the top surface of the substrate W.

FIG. 12 illustrates a flow chart showing a semiconductor fabrication method according to one or more embodiments of the present disclosure.

Referring to FIG. 12, a semiconductor fabrication method S may be provided. The semiconductor fabrication method S may be a way of manufacturing a semiconductor device by using the semiconductor fabrication system (see MS of FIG. 1) discussed with reference to FIGS. 1 to 11. The semiconductor fabrication method S may include placing a substrate through a loadport on a substrate processor (S1), allowing the substrate processor to process the substrate (S2), unloading the substrate through the loadport from the substrate processor (S3), and using a cleaning apparatus to clean the loadport (S4).

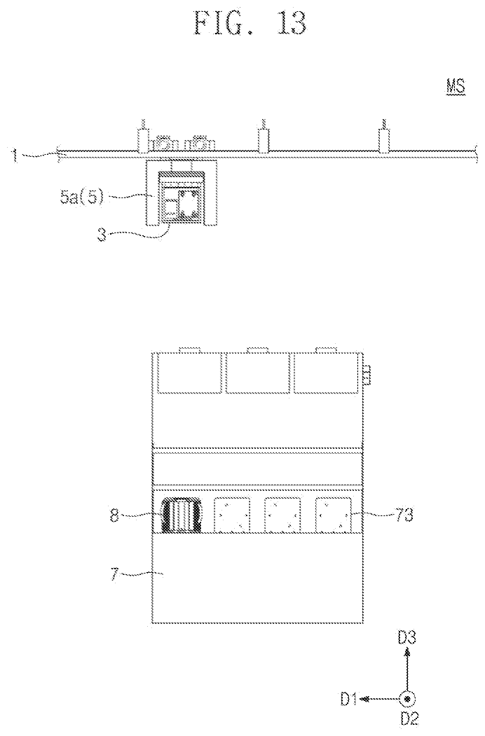

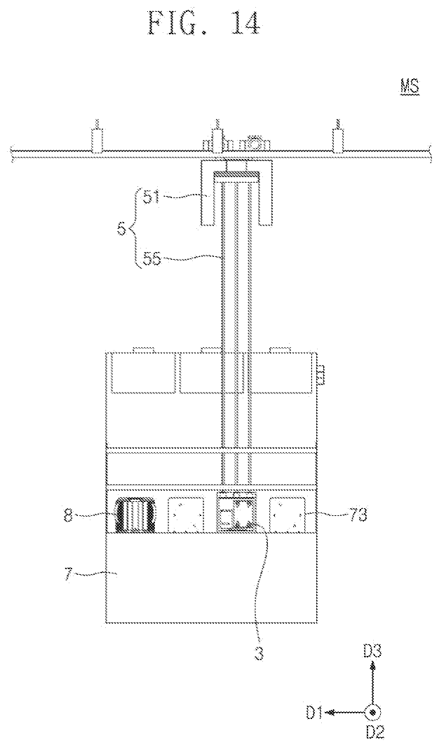

The semiconductor fabrication method S of FIG. 12 will be discussed below with reference to FIGS. 13 to 15.

FIGS. 13 to 15 illustrate diagrams showing a semiconductor fabrication method according to the flow chart of FIG. 12.

Referring to FIGS. 1 and 12, the substrate placing operation S1 may include allowing the second OHT 5b to place the substrate delivery apparatus 8 on the substrate loader 7. In a state where the substrate delivery apparatus 8 is disposed on the substrate loader 7, a substrate in the substrate delivery apparatus 8 may be transferred to the substrate processor A.

The substrate processing operation S2 may include allowing the substrate processor A to perform a process on a substrate. For example, when the substrate processor A is the etching chamber discussed with reference to FIG. 10, the substrate processor A may perform an etching process on a substrate. For another example, when the substrate processor A is the cleaning chamber discussed with reference to FIG. 11, the substrate processor A may perform a cleaning process on a substrate. The present disclosure, however, is not limited thereto, and the substrate processor A may be configured to perform various processes on a substrate.

The substrate unloading operation S3 may include allowing a substrate released from the substrate processor A to be inserted into the substrate delivery apparatus (see 8 of FIG. 9) disposed on the loadport (see 73 of FIG. 9). Afterwards, the second OHT 5b may transport the substrate delivery apparatus 8 into which a substrate is inserted.

Referring to FIGS. 12, 13, and 14, the loadport cleaning operation S4 may include using the cleaner 3 to clean the loadport 73. Using the cleaner 3 to clean the loadport 73 may include placing the cleaner 3 on the loadport 73. For example, the cleaner 3 combined with the first OHT Sa may move downwardly by the hoist 55 to be disposed on the loadport 73.

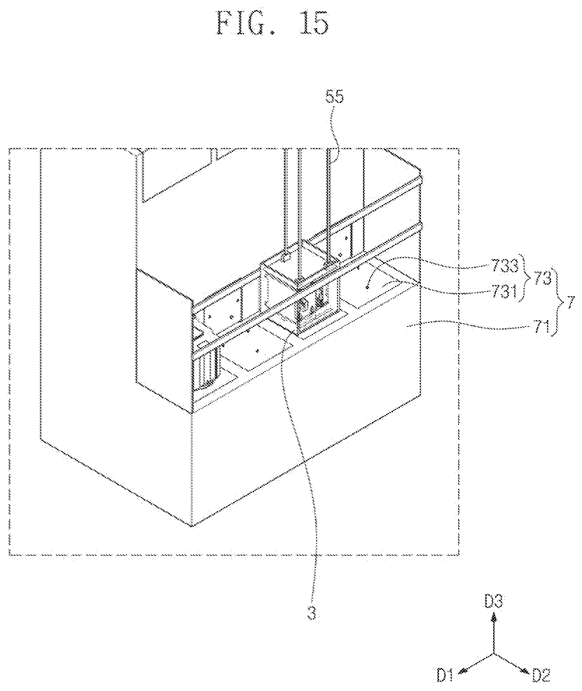

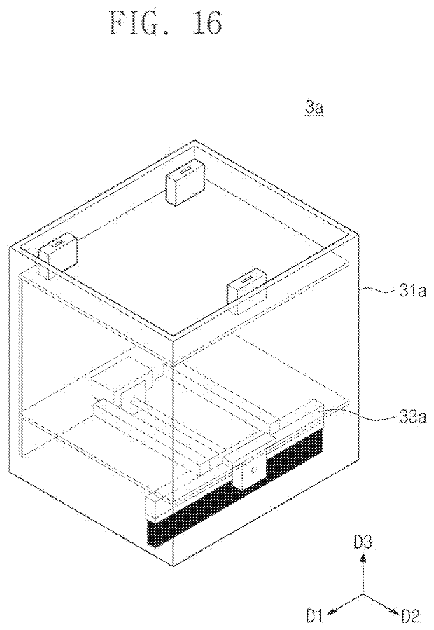

Referring to FIGS. 12 and 15, using the cleaner 3 to clean the loadport 73 may further include allowing the cleaner (see 33 of FIG. 5) to remove particles on the loadport 73. For example, the intake device 331 may use the intake pipe 333 to absorb particles positioned in a space below the housing 31. The particles on the loadport 73 may be inhaled (i.e., drawn in) through the intake pipe 333 to the intake device 331. Therefore, the particles on the loadport 73 may be removed from the loadport 73.

According to a cleaner, a semiconductor fabrication system including the same, and a semiconductor fabrication method using the same in accordance with one or more embodiments of the present disclosure, contaminants such as particles may be removed from a loadport. For example, particles may be removed which fall from an OHT rail toward the loadport. Therefore, it may be possible to prevent diffusion of contaminants, such as particles, on the loadport.

According to a cleaner, a semiconductor fabrication system including the same, and a semiconductor fabrication method using the same in accordance with one or more embodiments of the present disclosure, a conventional OHT rail may be used to clean a loadport. For example, the cleaner may be combined with an OHT that moves along the OHT rail, and a plurality of loadports located at various locations may be automatically cleaned. Accordingly, prompt work may be possible.

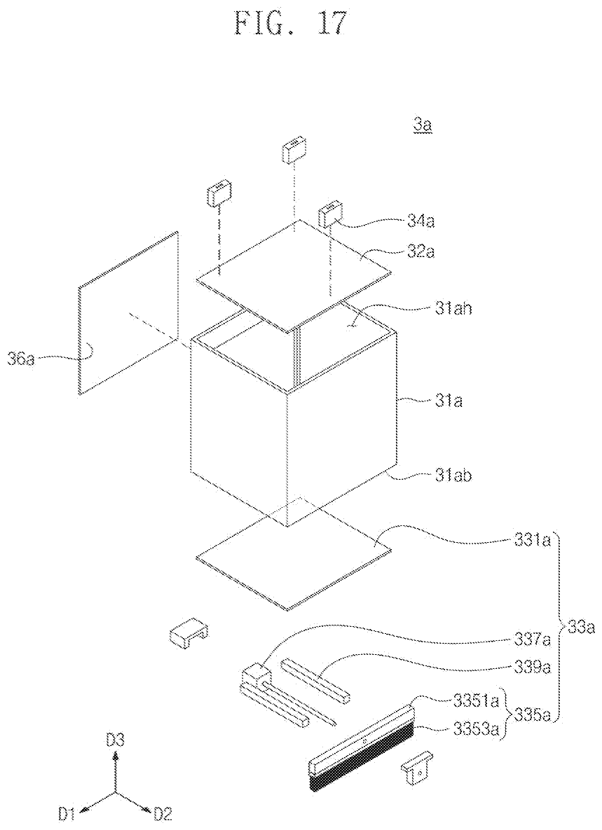

FIG. 16 illustrates a perspective view showing a cleaner according to one or more embodiments of the present disclosure. FIG. 17 illustrates an exploded perspective view showing a cleaner according to one or more embodiments of the present disclosure.

The following will omit a description of components the same as or similar to those discussed with reference to FIGS. 1 to 15.

Referring to FIGS. 16 and 17, a cleaner 3a may include a housing 31a, a cleaner 33a, an upper cover 32a, a side cover 36a, and a coupling member 34a. The housing 31a, the upper cover 32a, the side cover 36a, and the coupling member 34a may be substantially the same as or similar to those discussed with reference to FIG. 5.

At least a portion of the cleaner 33a may be inserted into an inner space 31ah provided by the housing 31a. The cleaner 33a may be exposed by a bottom surface 31ab of the housing 31a. Therefore, the cleaner 33a may remove particles positioned in a space below the housing 31a. The cleaner 33a may include a coupling plate 331a, a brush 335a, a guide bar 339a, and a brush driver 337a.

The coupling plate 331a may be combined with the housing 31a. The brush 335a may extend in the first direction D1. The brush 335a may include a brush support member 3351a and a brush body 3353a. A lower end of the brush 335a may be positioned lower than the bottom surface 31ab of the housing 31a. For example, at least a portion of the brush body 3353a may be positioned lower than the bottom surface 31ab of the housing 31a.

The guide bar 339a may extend in the second direction D2. The brush 335a may move in the second direction D2 along the guide bar 339a. The brush driver 337a may drive the brush 335a to move in the second direction D2. The brush driver 337a may include an actuator, such as a motor. In a state where the cleaner 3a is disposed on the loadport (see 73 of FIG. 15), the brush 335a may move in the second direction D2 to remove particles on the loadport 73.

According to a cleaner, a semiconductor fabrication system including the same, and a semiconductor fabrication method using the same in accordance with one or more embodiments of the present disclosure, contaminants such as particles may be removed from a loadport.

According to a cleaner, a semiconductor fabrication system including the same, and a semiconductor fabrication method using the same in accordance with one or more embodiments of the present disclosure, it may be possible to prevent diffusion of contaminants such as particles.

According to a cleaner, a semiconductor fabrication system including the same, and a semiconductor fabrication method using the same in accordance with one or more embodiments of the present disclosure, an OHT rail may be utilized to clean a loadport.

Effects of the present disclosure are not limited to those mentioned above, and other effects which have not been mentioned above will be clearly understood to those skilled in the art from the foregoing description.

Although the present disclosure has been described in connection with one or more embodiments of the present disclosure illustrated in the accompanying drawings, it will be understood to those skilled in the art that various changes and modifications may be made without departing from the technical spirit and essential feature of the present disclosure. It therefore will be understood that the embodiments described above are just illustrative but not limitative in all aspects.

What is claimed is:

1. A cleaning apparatus, comprising:
a housing that provides an inner space; and
a cleaner at least partially disposed within the inner space,
wherein the housing comprises:
a slit that is upwardly recessed from a bottom surface of the housing and is connected to the inner space; and
a plurality of placement holes that upwardly extend from the bottom surface of the housing, and
wherein the cleaner comprises:
an intake device disposed within the inner space; and
an intake pipe comprising a first end and a second end, wherein the first end is connected to the intake device and the second end is connected to the slit.

2. The cleaning apparatus of claim 1,
wherein the cleaner further comprises a nozzle cover disposed within the slit,
wherein the nozzle cover comprises a nozzle hole that vertically penetrates the nozzle cover, and
wherein the second end of the intake pipe is connected to the nozzle hole.

3. The cleaning apparatus of claim 1, wherein
the slit extends horizontally in a first direction, and
at least one of the plurality of placement holes does not overlap the slit.

4. The cleaning apparatus of claim 3, wherein a width of the slit in a second direction decreases in an upward direction, the second direction being a horizontal direction that intersects the first direction.

5. The cleaning apparatus of claim 1,
wherein the housing further comprises a sensor receiving hole that is upwardly recessed from the bottom surface of the housing, and
wherein the sensor receiving hole does not overlap any of the slit and the plurality of placement holes.

6. The cleaning apparatus of claim 5, wherein a thickness of the sensor receiving hole is in a range of about 5 mm to about 11 mm.

7. The cleaning apparatus of claim 1, wherein
the plurality of placement holes consists of three placement holes, and
the three placement holes are disposed to constitute a triangular shape when viewed in plan.

8. The cleaning apparatus of claim 1, wherein the intake device comprises:
a pump connected to the first end of the intake pipe; and
an intake motor configured to drive the pump.

9. A semiconductor fabrication system, comprising:
an overhead hoist transport (OHT) rail;
a first OHT configured to move along the OHT rail; and
a cleaning apparatus attached to the first OHT,
wherein the cleaning apparatus comprises:
a housing that provides an inner space; and
a cleaner configured to remove a particle in a space below the housing, and
wherein the cleaner is at least partially disposed within the inner space and is exposed to an exterior of the housing on a bottom surface of the housing.

10. The semiconductor fabrication system of claim 9,
wherein the housing comprises a slit that is upwardly recessed from the bottom surface of the housing and is connected to the inner space, and
wherein the cleaner comprises:
an intake device disposed within the inner space; and
an intake pipe comprising a first end and a second end, wherein the first end is connected to the intake device and the second end is connected to the slit.

11. The semiconductor fabrication system of claim 9,
wherein the cleaner comprises:
a brush that extends horizontally in a first direction; and
a brush driver configured to cause the brush to move horizontally in a second direction that intersects the first direction, and
wherein a lower end of the brush is located below the bottom surface of the housing.

12. The semiconductor fabrication system of claim 9,
wherein the first OHT comprises:
an OHT body that provides an accommodation space; and
a hoist attached to the OHT body and extending vertically,
wherein the hoist is attached to the cleaning apparatus, and
wherein the cleaning apparatus is connected to the OHT body through the hoist.

13. The semiconductor fabrication system of claim 9, further comprising:
a second OHT configured to move along the OHT rail; and
a substrate delivery apparatus attached to the second OHT,
wherein the substrate delivery apparatus comprises one of a cassette and a front opening unified pod.

14. The semiconductor fabrication system of claim 9, further comprising a loadport that is downwardly spaced apart from the OHT rail,
wherein the loadport comprises:
a support plate; and
a plurality of pins that upwardly extend from a top surface of the support plate.

15. The semiconductor fabrication system of claim 14, further comprising:
a substrate processor that is spaced apart in a horizontal direction from the loadport,
wherein the substrate processor comprises at least one of an etching chamber, a deposition chamber, a polishing chamber, an ion implantation chamber, a metal line process chamber, a measurement chamber, a photolithography chamber, and a cleaning chamber.

16. A semiconductor fabrication method, comprising:
placing a substrate through a loadport on a substrate processor;
processing the substrate using the substrate processor;
unloading the substrate through the loadport from the substrate processor;
placing a cleaner on the loadport using a first overhead hoist transport (OHT) that is upwardly spaced apart from the loadport; and
removing a particle on the loadport using the cleaner.

17. The semiconductor fabrication method of claim 16,
wherein placing the cleaner on the loadport using the first OHT comprises:
moving the first OHT along an OHT rail upwardly spaced apart from the loadport; and
lowering the cleaner using a hoist of the first OHT.

18. The semiconductor fabrication method of claim 17,
wherein placing the substrate through the loadport on the substrate processor comprises:
placing the substrate on the loadport using a second OHT, wherein the second OHT is configured to move along the OHT rail; and
transferring the substrate from the loadport to the substrate processor.

19. The semiconductor fabrication method of claim 16,
wherein the cleaner comprises:
an intake device; and
an intake pipe comprising a first end and a second end, wherein the first end is connected to the intake device and the second end is disposed on the loadport, and
wherein removing the particle on the loadport using the cleaner comprises causing the intake device to cause the particle on the loadport to be drawn in through the intake pipe.

20. The semiconductor fabrication method of claim 16,
wherein the cleaner comprises:
a brush that extends horizontally in a first direction; and
a brush driver configured to cause the brush to move horizontally in a second direction that intersects the first direction, and
wherein removing the particle on the loadport using the cleaner comprises causing the brush to move in the second direction.
